(19) United States
(12) Patent Application Publication
(10) Pub. No.: US 2009/0031179 A1
(43) Pub. Date: Jan. 29, 2009

(54) JTAG TEST CODE AND DATA COMPILER AND METHOD

(76) Inventor: Sam Michael, Mill Creek, WA (US)

Correspondence Address: Sam Michael, PO Box 12081, Mill Creek, WA, 98082, US

(21) Appl. No.: 11/829,902

(22) Filed: Jul. 28, 2007

(51) Int. Cl. G06F 9/30; G01R 31/3187

(52) U.S. Cl. 714/727; 717/139; 714/E11.155

(57) ABSTRACT

A software compiler is described here that is capable of analyzing JTAG test functions and translating them into code and date usable and accessible by a JTAG-bus controller hardware circuit. The compiler is capable of reading instructions and data information not directly usable by a JTAG-bus controller, such as Serial Victor Format, and generating instructions and data executable by a JTAG-bus controller hardware circuit. This allows the JTAG-bus controller to directly access such compiled code during the test without using an interpreter to translate such information before executing them.

The Compiler is also capable of allocating and managing a memory structure to store multiple data structure at the same time so that it will be ready to be used by the JTAG-bus controller during scan operations. This will allow for an expedited execution of the test functions since the data is already translated into directly readable and writable formats.

### BACKGROUND OF THE INVENTION

1. Field of the Invention

This invention pertains to test software used to test and debug electrical circuits and, more particularly, such devices that use a Joint Test Action Group (JTAG) port.

2. Description of the Related Art

With the complexity and increase of pin-count of new computer chips and the dense assembly of these chips on circuit boards, it becomes increasingly difficult to test and debug the circuit boards after being assembled. A group of leading electronic companies has joint joined forces and developed a standard test port to be built on every chip. The purpose of this test port is to allow connection to a test tool to validate the connection of each pin on the chip. Some chips add more functionality to this test port to provide access to virtually any resource inside the chip such as RAM, registers or I/O ports. One example of an in situ test port is the “JTAG” (Joint Test Action Group) test port adopted by the Institute of Electrical and Electronics Engineers, Inc, and defined as the IEEE standard 1149.1.

A common use of a test port is to test the components of a circuit board such as memory, Flash memory, Input/output chips and the on-board CPU. The test port can also be used to test the solder joints and the functionality of some of the onboard chips, and to program FLASH memory chips.

The common method of testing such circuit is to use a JTAG bus-master controller to control the JTAG bus and all the devices under test connected to this controller. The JTAG-bus controller is normally enclosed in a test equipment which has its own CPU and memory as shown in FIG. 1. The test information is normally provided in a text or a preparatory format such as Serial Victor Format (SVF), BSDL format or a like. The test tool CPU would normally be running a software interpreter to analyze such information and issue the appropriate commands to the JTAG-bus controller to execute the test. Herrmann et al. (U.S. Pat. No. 6,134,707) provided a method of using a software tool to interpret such a test code for programming and testing chips.

One disadvantage of this method is the repeated use of the interpreter code if the test procedure has to be rerun more than one time. For each test cycle, the interpreter has to read the test code, analyze it and generate the appropriate commands for the JTAG-test bus controller. This consumes additional time which slows the test cycle.

### SUMMARY OF THE INVENTION

It is an object of the present invention to provide a JTAG code compiler that can compile the test code at once and then store the data and code to be executed by the JTAG-bus controller in memory so that it can be accessed repeatedly without the need to interpret it every time the test is run.

The JTAG code compiler can be either executed using the test tool CPU or using another computer and then transferred to the test tool for execution.

The compiler will read the provided test information which could be in text, SVF, BSDL or any other format not directly executable by the JTAG-bus controller. This information would normally need interpretation before execution by the JTAG-bus controller. The compiler will generate JTAG-bus transactions that are directly executable by the JTAG-bus controller and store it in memory for execution. The data used for the test, such as test victors, would be translated into formats, such as binary format, that can be stored in the memory ready for execution and directly supplied to the JTAG-bus controller. The compiler should have the ability to manage and allocate memory spaces for code and data storage so that it can be accessible during test execution. Using such memory management, multiple scan data can be stored and ready for test execution.

Any of these features if integrated in the current solution will help increase the test speed. Combining all of these features in a single solution adds a lot of speed to the existing solution.

### BRIEF DESCRIPTION OF THE DRAWINGS

FIG. 1 is a schematic of a test tool using an interpreter to execute the test data in prior art.

FIG. 2 is a schematic of the new setup with the compiler code residing in the memory of the test tool.

FIG. 3 shows the work flow of the compiler software to compile the test information to a format that is directly executable by the JTAG-bus controller.

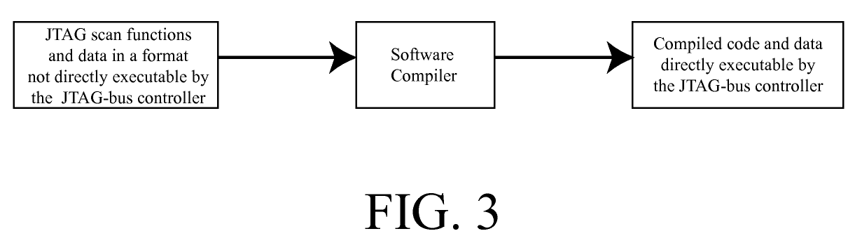

### DESCRIPTION OF THE PREFERRED EMBODIMENT (S)

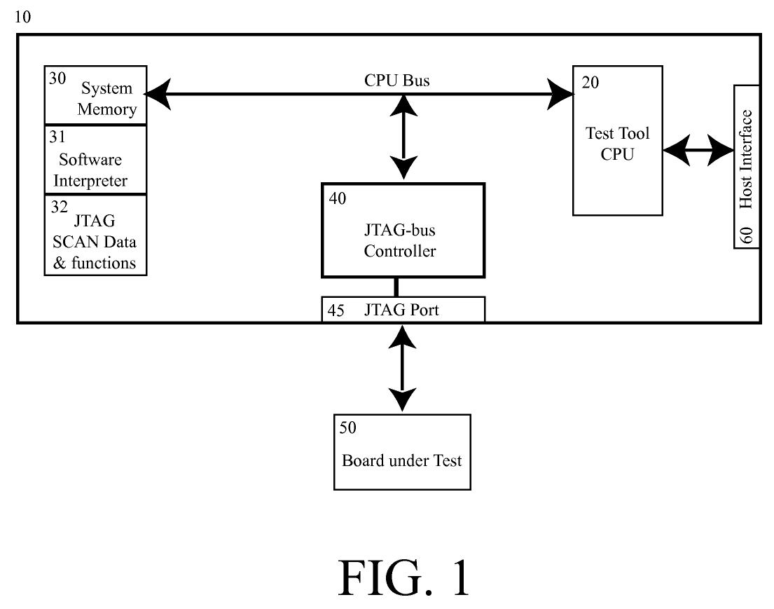

Referring to the accompanying FIG. 1, there is shown and described a test tool generally used to test electronic components using the JTAG port. The test tool has its own CPU (20) to control the test procedure. The CPU is connected to the system memory structure that is capable of storing a software interpreter to analyze test data and functions and generate the instructions and data needed for the JTAG-bus controller to execute JTAG-bus transactions. The test system in FIG. 1 also shows the JTAG-bus controller connected to and controlled by the CPU via the CPU bus. Such controller is capable of reading and writing data in predefined format such as binary format and executing predefined instructions that specify JTAG-bus transactions such as SCAN_IR, SCAN_DR and initiate JTAG-bus state changes. The test tool is connected to the host computer via the host interface (60) to receive test information. It is also connected to a system under test (50) via a JTAG port (45). In the prior art, the CPU reads the test data in text format, BSDL format, Serial Victor Format (SVF) or any other format that is not directly executable by the JTAG-bus controller. The system uses a software interpreter residing in the memory structure to translate the test data into instructions and data scans that specify discrete JTAG-bus transactions to be used with the JTAG-bus controller.

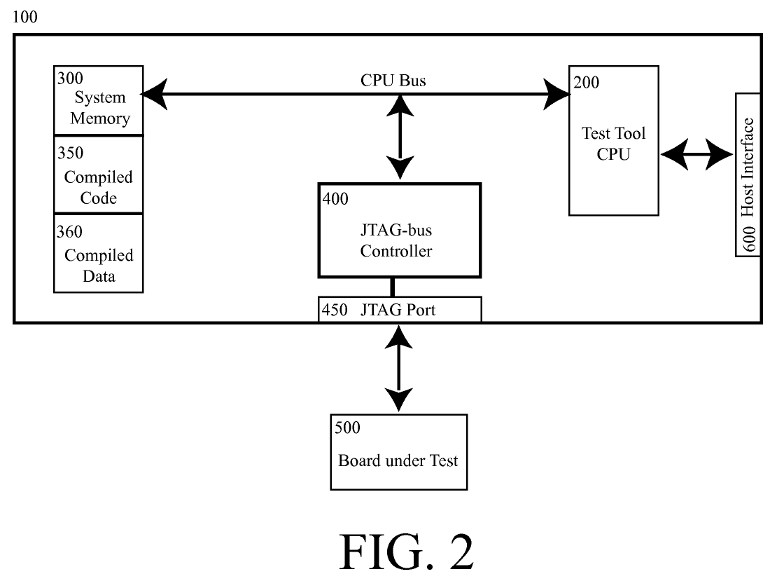

Referring to FIG. 2, the memory structure is used to store translated or compiled instructions and data ready to be used with the JTAG-bus controller (400). The JTAG-bus controller is designed to execute specific predefined JTAG-bus functions that are limited to executing instruction and data scans and initiating JTAG-bus state changes. It also reads and writes the data in predefined format such as binary format. The compiler has to run once at the beginning of the test cycle to generate the instructions and data used by the JTAG-bus controller. These data and instructions will be stored in memory for later use by the JTAG-bus controller and can be sent to the controller using a direct memory access (DMA) device or similar devices without the need for any further data processing from the test tool CPU. The compiled code does not have to include any other code executable by the test tool CPU or any other device to facilitate the test procedure. The test tool CPU can be optionally used as a data transfer device to replace the DMA device.

The compiler does not have to generate any code for execution by any other device in addition to the instructions used by the JTAG-bus controller. The test tool CPU can be used to start the test procedure and setup the initial test parameters but is not needed during the execution of the test. This can be done as a part of the operating system functionality of the test tool CPU that allows it to receive the compiler output and store it in memory to be ready for delivery and execution by the JTAG-bus controller. The JTAG-bus controller can use one or multiple DMA request and acknowledge signals to request data and instructions from the memory structure. These data and instructions are to be used by the JTAG-bus controller and are different from data scans and instructions scans that will be sent to the TAP controllers to execute JTAG test functions.

An example for such a function is to initiate a SCAN-DR function in a SVF format. The SVF code to be executed is:

SDR 32 TDI (89ABCDEF);

This statement is used to send the value 0X89ABCDEF to the object under test. The incoming date from the object under test will be stored in a separate location.

For this code, the compiler will generate the command for the JTAG-bus controller to initiate the SCAN-DR function for 32-bit of data and will allocate the needed memory space (8 bytes) to store the data-in and data-out values for the operation and additionally will attach pointers to said instruction to specify said memory spaces to be used with the generated instruction to be executed by the JTAG-bus controller. It can optionally set the end state of the JTAG bus.

At execution, the instruction will be sent to the JTAG-bus controller and the data read from memory and written to the controller. The incoming date from the JTAG-bus will be written to the memory space allocated by the compiler. As stated before, the data and instructions can be moved from the memory to the controller using a DMA controller or a similar device.

The JTAG-bus controller can be also modified to allow the direct access to the instructions and data from the memory structure. This will increase the speed of the test procedure.

The compiler will be able to compile multiple JTAG functions and allocate and manage multiple memory spaces to store scan data. It does that by dividing a large memory space to smaller spaces each capable of storing data for a specific JTAG function. Some of the data that are input from the JTAG-bus for one function can be used as output data in a following function. In such a case, the compiler will allocate a single memory structure and allocate its address pointers to two functions one as input and the other as output, which allows a more efficient use of the memory space.

In compliance with the statute, the invention described herein has been described in language more or less specific as to structural features. It should be understood; however, that the invention is not limited to the specific features shown, since the means and construction shown, is comprised only of the preferred embodiments for putting the invention into effect. The invention is therefore claimed in any of its forms or modifications within the legitimate and valid scope of the amended claims, appropriately interpreted in accordance with the doctrine of equivalents.

I claim:

1. A JTAG code compiler capable of reading multiple JTAG test functions, victors and data in formats not directly executable by a JTAG-bus controller hardware circuit and of translating them into code storable in memory and directly readable and executable by a JTAG-bus controller without the use of additional components, code executable by additional components or interpreter to translate the generated code during the test execution phase;
Whereas the JTAG-bus controller is capable of executing a set of predefined functions such as JTAG data and instruction scans, initiating JTAG-bus state changes as well as reading and writing scan data in predefined format.

2. The JTAG code compiler, as recited in claim 1, whereas said compiler is capable of managing a memory space by dividing it into smaller spaces allowing concurrent storage of multiple test code and data segments in such memory space.

3. The JTAG code compiler, as recited in claim 1, where the compiler code can be executed on the test-tool CPU to generate the executable code.

4. The JTAG code compiler, as recited in claim 1, where the compiler code is executed on an external computer and the generated compiled code is transferred to the test-tool for execution by the JTAG-bus controller.

5. A method of executing JTAG test and scan functions, the method comprising:
A. Using a software compiler to read and compile the JTAG functions and data victors provided in formats not directly executable by a JTAG-bus controller hardware circuit into instructions and data directly executable and readable by the JTAG-bus controller circuit; said compiled code and data are readable and executable by the JTAG-bus controller without the use of additional components, code executable by additional components or interpreter to translate the generated code during the test execution phase;
B. Storing such compiled data and instructions into memory accessible by said JTAG-bus controller;
C. Providing a mean to transfer the data and instructions between the memory and the JTAG-bus controller circuit; and,
D. Running the JTAG-bus controller circuit to execute the compiled data and instructions by receiving them from memory and executing them;
Whereas the JTAG-bus controller is only capable of executing a set of predefined functions such as JTAG data and instruction scans, initiating JTAG-bus state changes as well as reading and writing scan data in predefined format.

6. The method of executing JTAG test and scan functions, as recited in claim 5, where the JTAG-bus controller is connected to hardware components under test to execute said test functions by sending and receiving scan data to and from the components under test.
